(19) United States
(12) Patent Application Publication
(10) Pub. No.: US 2021/0172205 A1
(43) Pub. Date: Jun. 10, 2021

(54) Securing Apparatus, System and Method

(71) Applicant: DeWalch Technologies, Inc., Houston, TX (US)

(72) Inventors: Tyler Dean Todd, II, Houston, TX (US); Norman Binz DeWalch, Houston, TX (US); Michael Andre Evans, Houston, TX (US)

(73) Assignee: DeWalch Technologies, Inc., Houston, TX (US)

(21) Appl. No.: 16/988,660

(22) Filed: Aug. 9, 2020

Related U.S. Application Data
(63) Continuation of application No. 13/953,734, filed on Jul. 29, 2013, now abandoned.

(51) Int. Cl. E05B 65/00; G01R 22/06; F16B 41/00; F16B 2/06; G01R 11/24; E05B 67/36; F16B 21/16; E05B 73/00; E05B 67/38

(52) U.S. Cl. CPC E05B 65/0089; G01R 22/066; F16B 41/005; F16B 2/065; G01R 11/24; E05B 67/365; Y10T 70/558; Y10T 70/554; Y10T 70/40; E05B 73/0005; E05B 67/383; Y10T 70/5031; F16B 21/165

(57) ABSTRACT

The present invention relates to an apparatus and method for securing a box cover to a watthour meter socket box and relates to an apparatus, a system and method including a ring comprising an annular body portion and further comprising first and second tab members and a connective member disposed on the first tab member. The connective member comprises a fastening member comprising a fastener body portion forming a head section and a shaft section. The shaft section forms an open end, and the fastener body portion comprises a fastener interior surface defining a cavity extending axially from the open end and into at least the shaft section, and wherein the exterior surface of the shaft section forms a thread member. A receiver member is disposed on the second tab member, wherein the receiver member comprises an interior surface defining a receiving groove adapted to threadably receive the thread member of the shaft section, the first and second tab members being securable by the connective member and receiver member, and wherein the interior surface of the receiver member is configured for receiving a locking member, and the fastener interior surface is configured for interconnection with the locking member.

### CROSS-REFERENCE TO RELATED APPLICATION

This application is a continuation of application Ser. No. 13/953,734, filed Jul. 29, 2013.

All written material, figures, content and other disclosure in the above referenced application is hereby incorporated by reference.

### BACKGROUND OF THE INVENTION

The present invention relates generally to a securing apparatus, and more specifically, it relates to a fastening and locking apparatus, system and method for securing at least one structure or a plurality of structures and may be used to secure a utility service enclosure, or for example, a watthour meter socket box to prevent unauthorized access.

In the electric utility industry, for example, a locking apparatus or seal is useful to secure access panels of enclosures containing electrical or metering equipment. Such a locking apparatus or seal also ideally includes tamper-evident features to indicate unwanted tampering with the seal or attempts to access a secured electrical meter box or the like.

Electrical service providers generally deliver electricity to their customers via power lines buried underground or distributed along poles or towers overhead. The provider's power lines are usually distributed from a power generation station to numerous sets of customer lines, so that customers can then use the power to satisfy their various electrical needs. To measure delivered power so that customers can be billed in proportion to their usage, service providers typically terminate their power lines at a customer's home or business facility through a metered socket box, various designs for which are well known.

A meter box is generally used by electric utility companies, however the invention herein may be used with other utility service enclosures in the gas, water, cable, TV utility industries, or in shipping or other industries as well.

An example of one previously known meter box consists of two sets of electrical posts, with a provider's transmission lines being connected to one set of posts, and the customer's service lines to the other set. In order to measure the amount of electricity a customer uses, the meter box is configured to accept a watt-hour meter or another electricity usage measurement device, which, when plugged into the socket box, permits transmission of electricity from the provider to the customer and allows the amount of transmitted electricity to be accurately measured, so that the provider can charge the customer for power usage at an appropriate rate.

The present invention is also applicable in situations where the customer's service lines are routed from the meter box to a breaker box so that electricity can be distributed to multiple service locations using additional sets of electrical lines or wires.

Presently, there are various types of meter socket boxes, each distinguished by the manner in which the meter is secured in place once it has been plugged into an electrical socket disposed in the meter box. Regarding FIG. 1, a ringed-type meter socket box 20 is illustrated. In order to hold an electricity meter 26 in place and prevent its removal from the meter socket box 20, both the meter 26 and meter socket box 20 incorporate a corresponding set of structures including a meter band and flange, respectively, that are retained together with an annular securable ring (not shown) which is sealable. The securable sealing ring is designed to encase and captivate the meter band and flange of the meter socket box 20 when the ends of the sealing ring are held or connected together.

However, with this type of design and certain locking devices, only one type of securing fastener or locking device may be used. For example, the sealing ring may only be secured using for example and lower security, threaded-type of fastening device. Other rings are secured using a higher security locking device or barrel lock, requiring a key, such a plunger lock or rotationally actuated barrel lock. However, these devices typically provide mounting hardware only for either a lower security fastening device or a higher security locking system, but not both.

In an attempt to overcome some of these shortcomings, one device, for example, that can be installed on ring-type meter socket boxes, provides a threaded fastener and receiver combination and then also separately located apertures in the ends of a ring adapted to receive a locking pin and housing assembly for locking together structures such as a watthour meter to a mounting flange of a watthour meter box. The device includes a ring with two ends; the ring ends provide one location or region for securing the fastener and receiver together and a separate location or region for securing the locking pin and housing together. There are also other devices that comprise two ring ends having interconnecting structures with one ring end including, for example, a tab member and the other ring end including an aperture adapted to receive the tab member to interconnect the ring ends. The tab member also forms an opening adapted to receive a frangible wire seal tab or the like. After the ring ends are interconnected, the wire seal tab may be inserted through the tab member opening and secured. With this configuration, breaking or cutting the frangible wire seal tab would provide evidence that the device had been tampered with. However, these securing devices do not sufficiently inhibit access to the interconnecting structures and are relatively easy to defeat.

(It should be noted that any information referred to above or herein is not intended to constitute an admission that such information is in fact “material” or “prior art” for the present invention unless specifically designated as such).

There remains a need for a dual fastening and locking apparatus, system and method for securing at least one structure or a plurality of structures, which can more efficiently accommodate both fastening and locking devices and be used with a utility service enclosure, or for example, a meter box locking ring having, for example, flanged ends, or additionally, used to seal for example, utility enclosures, meter boxes, traffic light switching or control enclosures or trucking, shipping, airline or other transportation containers or enclosures. There is also a need for an apparatus having various configurations or modes that may be adapted for use in, for example, multiple fastening or locking applications, such as for use in lower security circumstances or higher security circumstances or both as well as to provide a device that can further be used for mid-range security applications. There is a further need for a lower cost or alternatively a higher cost applications depending on the level of security desired and for an apparatus which can be manufactured with fewer parts so as to be simple to use and provide desirable economic benefits.

Those of skill in the art will appreciate the example embodiments of the present invention which addresses the above exemplary, non-limiting needs and others.

### SUMMARY OF THE INVENTION

In one example embodiment, a securing system for use with an electricity meter and a meter socket box is provided. Turning again to the various drawings in FIGS. 2A-7C, similar named elements denote similar reference characters throughout the several views. The system comprises a primary connector comprising a connective member and a receiver member. The connective member comprises a fastening member comprising a fastener body portion forming a head section and a shaft section, the shaft section is insertable through a first aperture formed in a first tab member of a securing ring adapted for securing an electricity meter to a meter socket box. The shaft section forms an open end, and the fastener body portion comprises a fastener interior surface defining a cavity extending axially from the open end and into at least the shaft section. The exterior surface of the shaft section forms a thread member. A portion of the receiver member is insertable through second aperture formed in a second tab member of a securing ring adapted for securing an electricity meter to a meter socket box, the receiver member comprising an interior surface defining a receiving groove adapted to threadably receive the thread member of the shaft section, the first and second tab members being securable with the connective member and receiver member. The primary connector is configured for interconnection with a secondary connector. In another embodiment, the system further comprises a secondary connector comprising a locking member comprising a head member and a shaft member. The interior surface of the receiver member further defines a cylindrical bore therethrough being adapted to receive the shaft member, such that the fastener interior surface is configured for interconnecting the shaft member. In a further embodiment of the system, the shaft member of the locking member comprises at least one locking element. The shaft member of the locking member is insertable through the open end of the shaft section and into the cavity of the fastener body portion and the fastener interior surface is configured for interconnecting with the at least one locking element.

These and other aspects, features, and advantages of example embodiments of the present invention will become apparent from the drawings, the descriptions given herein, and the appended claims. Further aspects are also indicated herein in various example embodiments of the invention. However, it will be understood that the above-listed aspects, objectives and/or advantages of example embodiments are intended only as an aid in quickly understanding aspects of the example embodiments, are not intended to limit the embodiments of the invention in any way, and therefore do not form a comprehensive or restrictive list of aspects, objectives, and/or features, and/or advantages.

There has thus been outlined, rather broadly, features of example embodiments of the invention in order that the detailed description thereof may be better understood, and in order that the present contribution to the art may be better appreciated. There are additional features of example embodiments of invention that will be described hereinafter.

In this respect, before explaining at least one example embodiment of the invention in detail, it is to be understood that the example embodiments are not limited in its application to the details of construction and to the arrangements of the components set forth in the following description or illustrated in the drawings. Various example embodiments are capable of other further embodiments and of being practiced and carried out in various ways. Also, it is to be understood that the phraseology and terminology employed herein are for the purpose of the description and should not be regarded as limiting.

To the accomplishment of the above and related aspects, example embodiments of the invention may be embodied in the form illustrated in the accompanying drawings, attention being called to the fact, however, that the drawings are illustrative only, and that changes may be made in the specific construction illustrated.

### BRIEF DESCRIPTION OF THE DRAWINGS

The drawings as noted below form part of the present specification and are included to further demonstrate certain aspects of example embodiments of the invention. Various other aspects, features and attendant advantages of the embodiments of the invention will become fully appreciated as the same becomes better understood when considered in conjunction with the accompanying drawings, in which like reference characters designate the same or similar parts throughout the several views, and wherein:

FIG. 1A is a perspective view of a watt-hour meter and enclosure.

FIG. 1B is a perspective view of a watt-hour meter and enclosure with exploded view of a meter ring assembly and plunger lock.

FIG. 2A is an exploded view of an embodiment of a ring assembly with fastening member retained by an o-ring.

FIG. 2B is a front view perspective of a ring assembly shown in FIG. 2A.

FIG. 3A is a perspective view of an embodiment of the receiving member.

FIG. 3B is a cross-sectional view of the receiving member shown in FIG. 3A.

FIG. 3C is a perspective view of the receiving member shown in FIG. 3A with collar deformed.

FIG. 3D is a cross-sectional view of the receiving member shown in FIG. 3A with collar deformed.

FIG. 3E is a perspective view of an embodiment of the fastening member.

FIG. 3F is another perspective view of the fastening member shown in FIG. 3E.

FIG. 3G is a cross-sectional view of the fastening member shown in FIG. 3E.

FIG. 4A is an exploded cross-sectional view of an embodiment of a ring assembly with fastening member retained by an o-ring and receiving member retained by deformed collar.

FIG. 4B is FIG. 4A collapsed.

FIG. 5A is an exploded perspective view of an embodiment of a ring assembly with fastening member retained by an o-ring with a plunger lock.

FIGS. 5A1 and 5A2, is perspective and plan view comprising a primary connector comprising a connective member and a receiver member and in a further embodiment, the system comprises a secondary connector.

FIG. 5B is a front view perspective of an embodiment of ring assembly with the fastening member retained by an o-ring with a plunger lock inserted to the locked position.

FIG. 5C is an exploded cross-sectional front perspective view of ring assembly shown in 5A.

FIG. 5D is FIG. 5C collapsed with a plunger lock in locked position.

FIG. 6A is an exploded cross-sectional view of an alternate embodiment of ring assembly with an alternate embodiment of the fastening member retained by a support member, receiving member retained by deformed collar, and a plunger lock.

FIG. 6B is FIG. 6A with a plunger lock in the locked position.

FIG. 7A and FIG. 7B are perspective views of an alternate embodiment of the fastening member.

FIG. 7C is a cross-sectional view of the fastening member shown in FIG. 7A and FIG. 7B.

FIG. 8A is an exploded view of an alternate embodiment of the ring assembly with the fastening member retained by an o-ring and the receiving member retained by deformed collar. Both the fastening member and the retaining members have slot apertures aligned for the acceptance of a seal tab.

FIG. 8B is a collapsed frontal view of the alternate embodiment shown in FIG. 8A.

FIG. 9A is a perspective view of an alternate embodiment of the receiving member having slot apertures for the acceptance of a seal tab.

FIG. 9B is a cross-sectional view of the receiving member shown in FIG. 9A.

FIG. 9C is a perspective view of an alternate embodiment of the receiving member with collar deformed having slot apertures for the acceptance of a seal tab.

FIG. 9D is a cross-sectional view of the receiving member shown in FIG. 9C.

FIG. 9E and FIG. 9F are perspective views of an alternate embodiment of the fastening member having slot apertures for the acceptance of a seal tab.

FIG. 9G is a cross-sectional view of the fastening member shown in FIG. 9E and FIG. 9F.

FIG. 10A is an exploded frontal cross-sectional view of an alternate embodiment of the ring assembly with the fastening member retained by an o-ring and the receiving member retained by deformed collar. Both the fastening member and the retaining members have slot apertures aligned for the acceptance of a seal tab.

FIG. 10B is a frontal cross-sectional view of the ring assembly shown in FIG. 10A.

FIG. 11A is a front exploded view of an alternate embodiment of the ring assembly with fastening member retained by an o-ring and a plunger lock. In this embodiment, the plunger lock is inserted from the same side as the fastening member.

FIG. 11B is a collapsed view of assembly shown in FIG. 11A with plunger lock inserted to the locked position.

FIG. 12A is a cross-sectional view of assembly shown in FIG. 11A.

FIG. 12B is a cross-sectional view of assembly shown in FIG. 11B.

While the present invention will be described in connection with presently preferred embodiments, it will be understood that it is not intended to limit the invention to those embodiments. On the contrary, it is intended to cover all alternatives, modifications, and equivalents included within the spirit of the invention and as defined in the appended claims.

### DETAILED DESCRIPTION OF THE INVENTION

Turning now descriptively to the drawings, in which similar reference characters denote similar elements throughout the several views, the attached figures illustrate an apparatus for securing a plurality of structures or a portion of a utility service enclosure and noted herein. For example, in one embodiment, the apparatus is used for securing a watthour meter socket ring so as to prevent the separation of two opposing tab members of the watthour meter socket box ring. The apparatus may be used for creating a tamper-evident seal by use of a seal tab as will be discussed further herein.

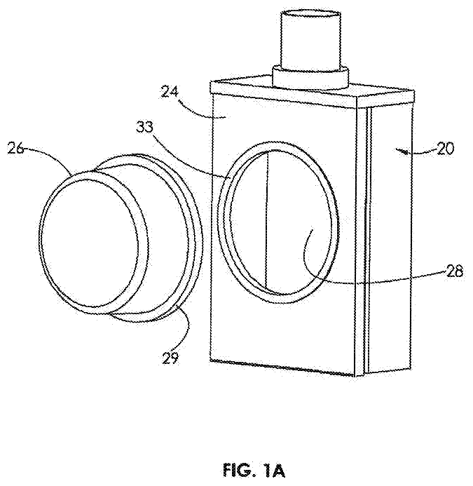

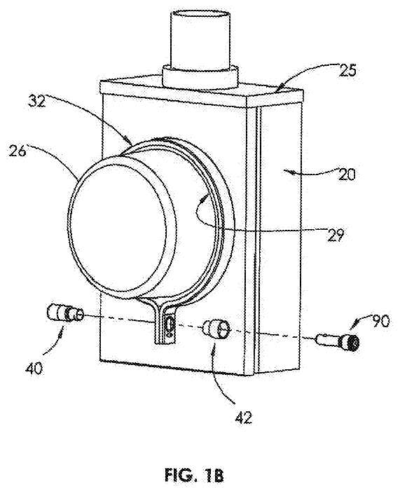

As briefly described earlier regarding FIG. 1, a ringed-type meter socket box 20 is illustrated. In order to hold an electricity meter 26 in place and prevent its removal from the meter socket box 20, both the meter 26 and meter socket box 20 incorporate a corresponding set of structures including a meter band and flange, respectively, that are retained together with an annular securable ring (not shown) which is sealable. The securable sealing ring is designed to encase and captivate the meter band and flange of the meter socket box 20 when the ends of the sealing ring are held or connected together.

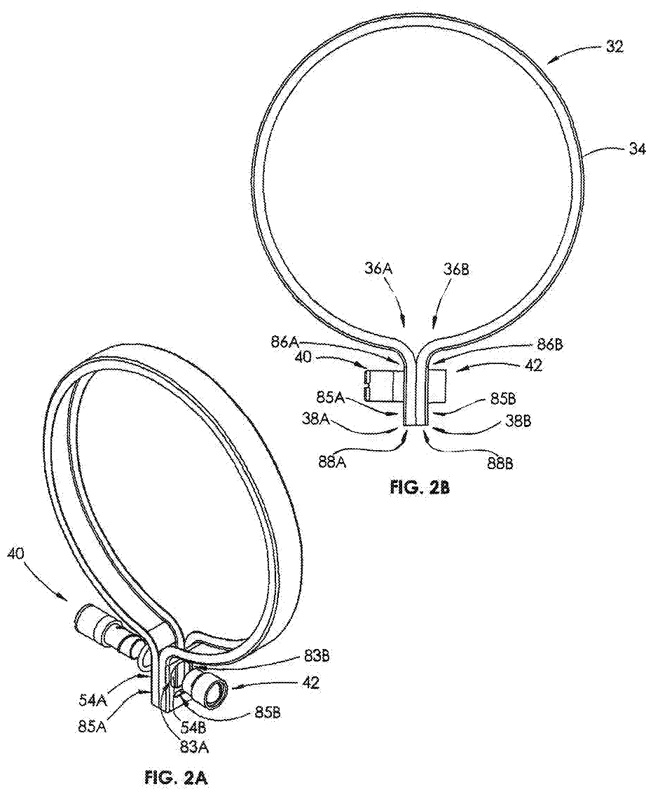

Referring now to FIGS. 1 and 2A-2B, according to an example embodiment, an apparatus for securing an electricity meter to a meter socket box is provided. A ring 32 comprises an annular body portion 34 having a split forming first and second ends 36A, 36B of the annular body portion. A first tab member 38A is disposed on the first ring end, and a second tab member 38B is disposed on the second ring end. In one example embodiment, the annular body portion is divided to comprise opposed ring ends and includes the first and second tab members and is formed from a metallic material to be discussed in further detail herein. The ring, including in some embodiments, the first and second tab members, may be formed from a band and the tab members may be formed from the annular body portion, and in some embodiments, extruded from a metal strip having a single-piece construction. In a further embodiment, the band material is rolled into the shape of an annular band and has a u-shaped cross-section. In still a further embodiment, the band is extruded from a solid rod. In other embodiments, the annular band is formed from a composite material, for example, from a hardened resin. In still other embodiments, the annular band is formed from plastic. With this configuration, the ring and tab members are designed, as generally noted, to secure the corresponding meter band and flange of the meter socket box when the tab members are connected together such as by a connection system including, for example, a fastener and a lock. It should also be noted that the contour of the band conforms with the meter band, with the tabs extending radially outward. In other embodiments, the tab members could be attached to the ring ends, by rivets or other means known to persons skilled in art, with the band body disposed immediately adjacent the meter mounting band.

As shown in FIGS. 2A-2B, a connective member 40 is disposed on the first tab member and a receiver member 42 is disposed on the second tab member 38A, 38B. In another example embodiment, a locking member is provided as will be explained further herein.

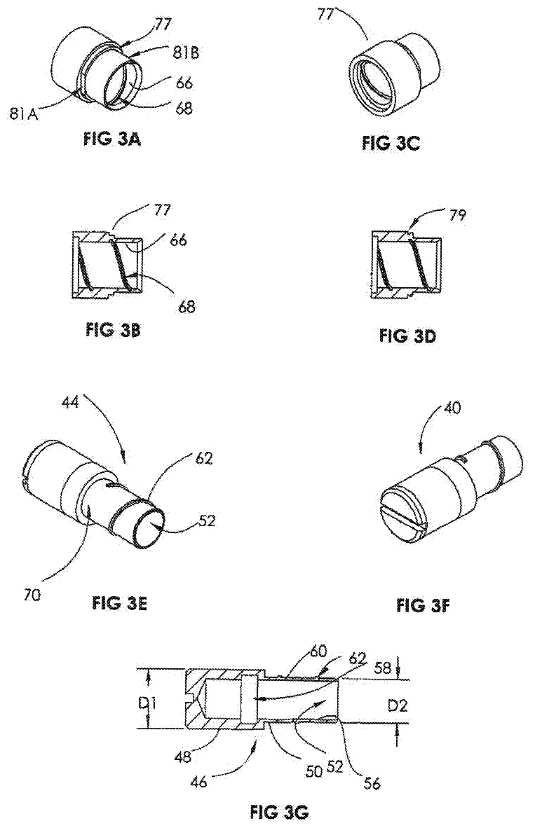

Referring to FIGS. 3A-3F, in an example embodiment, the connective member 40 comprises a comprising a fastening member 44 comprising a fastener body portion 46 forming a head section 48 and a shaft section 50 with the shaft section open at one end 52. The fastener body portion 46 comprises a fastener interior surface 56 defining a cavity 58 extending axially from the open end. In some embodiments, the cavity extends axially into at least the shaft section. In other embodiments, the cavity of the fastener body portion extends axially from the open end 52 and completely through the shaft section 50 and into at least a portion of the head section 48. The exterior surface 60 of the shaft section forms a thread member 62.

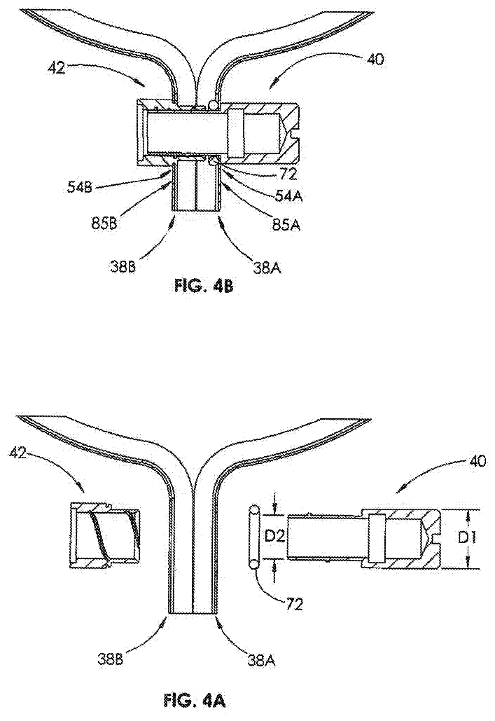

As shown in FIGS. 3A-3F and FIGS. 4A-4B, a receiver member 64 is disposed on the second tab member 38B. The receiver member comprises an interior surface 66 defining a receiving groove 68 adapted to threadably receive the thread member of the shaft section, such that the first and second tab members may be securable by the connective member and receiver member. Referring also to FIGS. 2A-2B, the first tab member 38A defines a first aperture 54A as noted and the fastening member 44 comprises a collar 70 suitable for supporting disposition of the fastening member through the first aperture. In addition, the second tab member 38B defines a second aperture 58B. The receiver member includes a support member for supporting disposition of the receiver member through the second aperture. In some embodiments, as shown in FIGS. 3A and 3B, support member 77 is suitable for nonrotatably supporting disposition of the receiver member through the second aperture.

Referring again to FIGS. 2A and 2B, a first slot 85A is formed on the first tab member 38A and a second slot 85B is formed on the second tab member 38B, and each of the first and second tab members 38A, 38B have a proximal end 86A, 86B near the rings ends 36A, 36B and a distal end 88A, 88B away from the rings ends. A wire seal tab (not shown), known to persons or ordinary skill in the art, is insertable through the first and second slots 85A, 85B and sealable. In an exemplary embodiment, the first and second slots are formed proximate the distal ends 88A, 88B. In another embodiment, the first and second slots are formed proximate the proximal ends 86A, 86B. In still another embodiment, the first and second slots are formed immediately adjacent the first and second ring ends 36A, 36B.

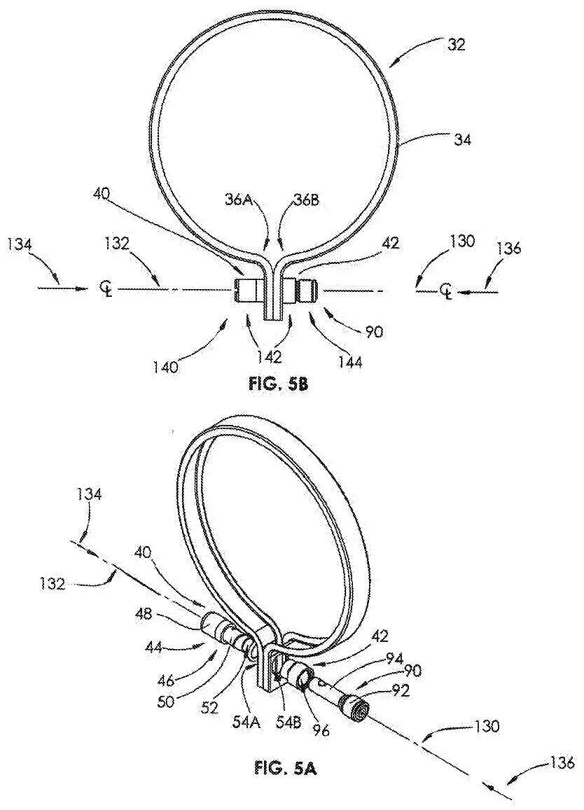

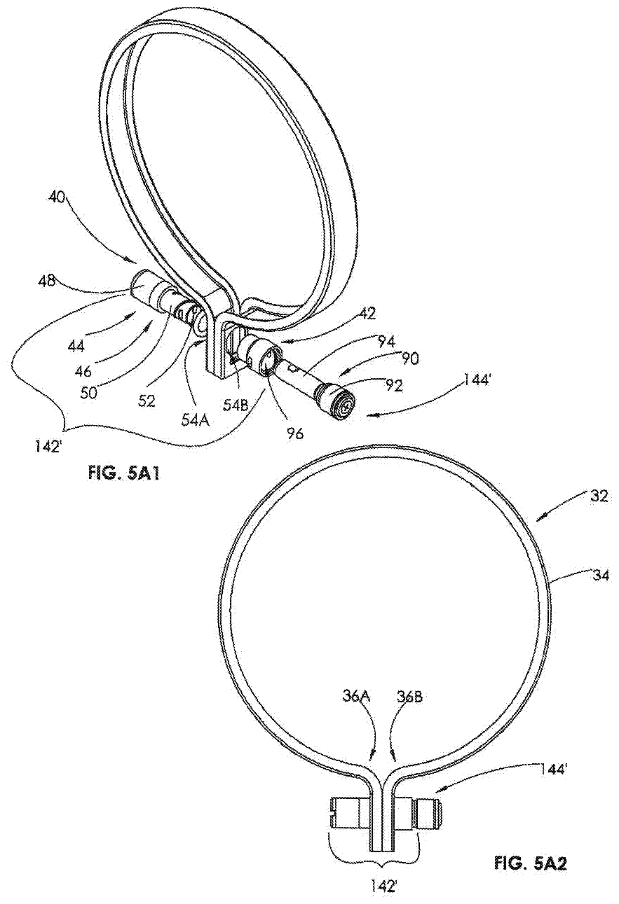

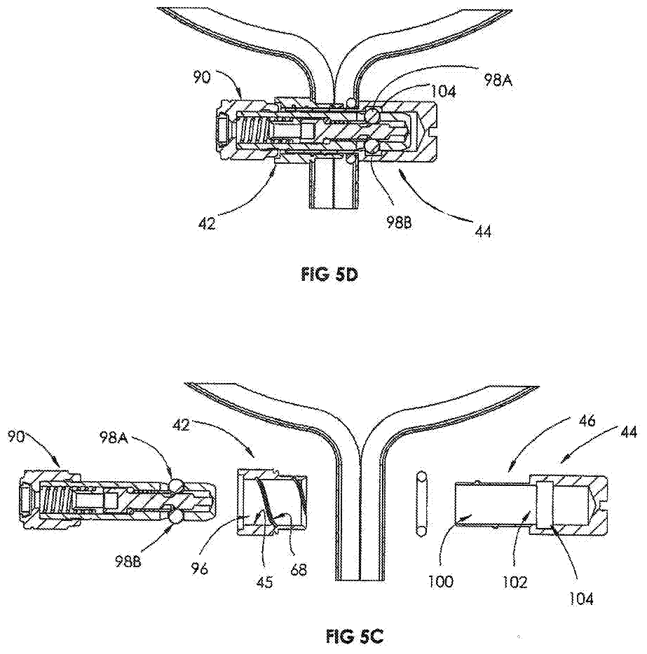

Turning now to FIGS. 5A-5D, in another embodiment, an apparatus for securing an electricity meter to a meter socket box is provided. A locking member 90 comprises a head member 92 and a shaft member 94. The interior surface of the receiver member 42 further defines a cylindrical bore 96 therethrough being adapted to receive the shaft member 94, such that the fastener interior surface is configured for interconnecting the shaft member. In one embodiment, the shaft member of the locking member includes at least one locking element. In an exemplary embodiment, the shaft member 94 preferably includes two locking elements 98A, 98B. The shaft member 94 of the locking member is insertable through the open end 52 of the shaft section 50 and into the cavity 100 of the fastener body portion, the fastener interior surface is configured for interconnecting with the at least one locking element in one embodiment. In an exemplary embodiment, the shaft member 94 preferably includes two locking elements 98A, 98B, and the fastener interior surface is configured for interconnecting with the two locking elements. In addition, in a further example embodiment, the locking elements 98A, 98B comprise locking balls as shown in FIG. 5C, in some embodiments, such as ball bearings or the like.

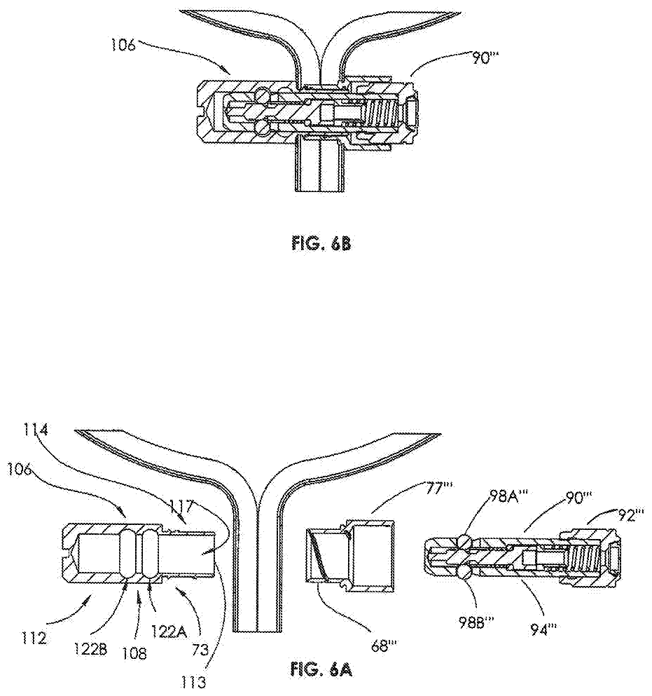

In an exemplary embodiment, the locking member comprises a barrel lock. For example, a type of barrel lock referred to as a SnapLock, shown in FIG. 6A, may be used; also, the various types shown in U.S. application Ser. No. 13/070,456, which is incorporated by reference in its entirety herein, may be used. In addition, a suitable disk tumbler lock may also be used having low-, mid-, or high-security applications, of the various types shown in U.S. Pat. No. 4,742,703, which is incorporated by reference in its entirety herein, may be used. In another embodiment, the locking member comprises a plunger lock; for example the types shown in U.S. application Ser. No. 13/070,456, which is incorporated by reference in its entirety herein, may be used.

As noted earlier, regarding FIGS. 3A-3F, in an example embodiment, the connective member 40 comprises a comprising a fastening member 44 comprising a fastener body portion 46 forming a head section 48 and a shaft section 50 with the shaft section open at one end 52. The fastener body portion 46 comprises a fastener interior surface 56 defining a cavity 58 extending axially from the open end. In an exemplary embodiment, the cavity of the fastener body portion extends axially from the open end 52 and completely through the shaft section 50 and into at least a portion of the head section 48. As noted earlier, the exterior surface 60 of the shaft section 50 forms a thread member 62.

As shown in FIGS. 5A-5D, the interior surface of the head section forms at least one recess adapted to receive the at least one locking element. In an exemplary embodiment, the interior surface of the head section forms one recess 104. The shaft member 94 preferably includes two locking elements 98A, 98B, and the head section of fastener interior surface is configured for interconnecting with the two locking elements 98A, 98B, preferably disposed, in an exemplary embodiment, in opposing relation on the shaft member, for example, as shown in FIG. 5D.

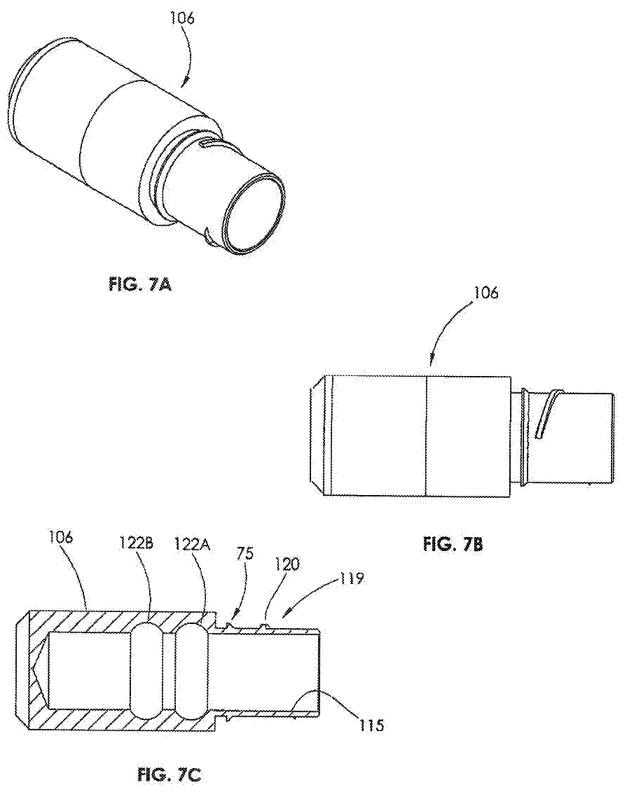

Referring now to FIGS. 6A-7C, another embodiment is shown of the connective member 106 which comprises a fastening member 108 comprising a fastener body portion 108, forming a head section 112 and a shaft section 114 with the shaft section open at one end 113. A receiver member 77′″ may be dimensioned and configured with a shorter interior surface comprising a thread receiving groove 68′″ so as to accommodate a barrel lock 90′″ comprising a head member 92′″ and shaft member 94′″. The fastener body portion 108 comprises a fastener interior surface 115 defining a cavity 117 extending axially from the open end 113. In some embodiments, the cavity extends axially into at least the shaft section. In other embodiments, the cavity of the fastener body portion 108 extends axially from the open end 113 and completely through the shaft section 114 and into at least a portion of the head section 112. The exterior surface 119 of the shaft section forms a thread member 120. The interior surface of the head section 112 forms at least two recesses 122A, 122B each being adapted to receive the locking elements of a shaft member of a locking member 90′″. It should be noted, that the shaft member of locking member 90′″ may vary in length depending on the depth, diameter and other size configurations of the cavity 117. For example, the cavity may be sized axially shorter or longer so as to complementarily accommodate interconnection of various shaft member types and lengths as would be known to those of ordinary skill in the art. It should also be recognized that the two recesses 122A, 122B are adapted to incrementally receive the locking elements, with the two recesses being formed in succession. In this way, the shaft member may be incrementally inserted into the head section 112 so as to draw together the first and second tab members 38A, 38B to foster adjustably securing an electricity meter to a meter socket box. More recesses could also be used in other embodiments as well. In addition, as noted earlier, in some embodiments the locking member 90′″ comprises a barrel lock. However, in certain embodiment, various sizes of the barrel lock, for example related to the head or shaft member, lengths and diameters and other aspects may be modified to function effectively for interconnection within the cavity 117. Also, as noted, for example, a type of barrel lock referred to as a SnapLock, shown in FIG. 6A, may be used; also, the various types shown in U.S. application Ser. No. 13/070,456, which is incorporated by reference in its entirety herein, may be used. In addition, a suitable disk tumbler lock may also be used having low-, mid-, or high-security applications, of the various types shown in U.S. Pat. No. 4,742,703, which is incorporated by reference in its entirety herein, may be used. In another embodiment, the locking member comprises a plunger lock; for example the types shown in U.S. application Ser. No. 13/070,456, which is incorporated by reference in its entirety herein, may be used.

Turning again to FIGS. 3A-3F, in other embodiments, the support member of the receiver member comprises an outer surface defining at least one rotation restricting stop surface, and preferably at least two rotation restricting stop surfaces 81A, 81B, and the second tab member 54B further defines the second aperture with at least one rotation restricting stop surface, and preferably at least two rotation restricting stop surfaces 83A, 83B, which are complementary with the rotation restricting stop surfaces 81A, 81B of the receiver member to prevent rotation while the fastener member is being threaded into the receiver member. In this way, the second aperture is adapted to receive and prevent rotation of the support member 77. Various rotation restricting, or anti-rotation, configurations may be used. For example, various types of configurations and stop surfaces shown in U.S. Pat. No. 7,213,424, which is incorporated by reference in its entirety herein, may be used.

It should also be noted that in another exemplary embodiment, the support member may also comprise a snap ring suitable for releaseably supporting disposition of the receiver member through the second aperture. With this configuration, the support member of the receiver member may be securely mounted to the tab member, but the receiver member may also be readily interchangeable in the event that receiver member is damaged or needs to be replaced, if using the ring and tandem interconnection system for, for example, low-, mid-, or high-security applications, however, the system is adaptable for other types of applications as well. For example, if using the system for a mid-security application, some or all components, including the ring, tab members, connective and receiver members and locking member may be formed from variously selected medium strength materials, such as a thinner gauge steel or thicker aluminum or high strength material such as steel. In a mid-security mode, for example, a desired assembly or combination of components may modified as desired in various example embodiments; for example, the ring may be formed with thinner gauge steel or aluminum, the connective member may be formed from steel, the receiver member may be formed from an aluminum material, providing, in some embodiments, a shearable region as noted herein, which shears when subject to a certain shear force, and the locking member may be a plunger lock rather than, for example, a case-hardened, high security rotationally actuated, disk tumbler lock. However, in other embodiments, any of various desired combinations of materials and locking members may be used depending on the application and if lower cost materials are desired for certain components of the assembly.

It should be noted, that the ring and interconnection systems as noted herein, are also interchangeable so as to foster field upgradeability. For example, if a particular meter box installation has a low-security configuration, including for example, in an example embodiment, an aluminum or thin gauge steel ring, a steel connective member, an aluminum receiver member, and no locking member used in tandem with the connective member and receiver, there may be reason to field upgrade the system. In some embodiments, for example, only a primary connector comprising a connective member and a receiver member may be used for a low- or mid-security application. If there is a need for higher security, the ring and interconnection systems are configurable to further include a secondary connector. In an exemplary embodiment, the secondary connector may comprise a plunger lock or a keyless insertion “SnapLock” as noted herein, for example, if a technician notices the system has been tampered with and wants to address the problem on the spot, in the field, without having to replace the ring with a ring that may or may not be available in the field. This offers operational efficiency and economic benefit of reducing required ring inventory as one ring satisfies multiple applications. However, in some example embodiments, if using the system for a high-security application, some or all components, including the ring, tab members, connective and receiver members and locking member may be formed from a high strength material such as case hardened carbon steel as described further herein. The ring may be made of 1008 or 1010 carbon steel, the connecting members made of 12L14 and the assembly would then be case hardened in a carbon nitriding heat treatment to make an attack with anything other than a grinding tool very difficult. It will also be appreciated, that such a configurable ring and interconnection system, enables a user to readily upgrade security ranges so as to meet security requirements and satisfy various market space requirements and needs. For example, various embodiments of the ring and interconnection system enable a user to readily upgrade in the field or in a work facility, from a low- to mid-security mode, or a mid- to high-security mode depending on, for example, utility revenue protection objectives. In addition, the various components and materials are configured to foster interchangeability to meet economical objectives or provide more cost-effective options using interconnection systems using less expensive materials. It will also be appreciated, that the various configurations also minimize the number of separate components required to effect a desired security mode.

As can be seen in FIGS. 2A-6B, certain components may be used for multiple functions which provide a notable technical advantage over other pre-existing sealing ring configurations as noted earlier. For example, the receiver may serve to threadably secure the connective member to form a primary connector. However, it also may be used to receive the shaft member of the locking member, when the locking member, such as a barrel lock is used as a secondary connector, in certain higher-level security applications.

In addition, the connective member has a dual-function or purpose as part of a primary connector and secondary connector. Moreover, the primary and secondary interconnection systems are adapted for coaxial alignment and interconnection using only first and second apertures on the first and second tab members. That is, this is one non-limiting advantage over other systems that do not have a coaxial alignment and insertion capability. Such other systems would require further apertures formed in the tab members, adding to the cost and complexity of the system and requiring more manufacturing operations to make the systems. With the configuration, as noted, the ring and interconnection system may be adapted for use in a low-security mode using just the connective member and receiver member or alternatively be adapted for use in a mid-to-high security mode using the connective member and receiver member and also the locking member.

Additionally, it should be noted that the preferred embodiment is the mid-range security system as noted. In this way, the user can decide to use a seal, plunger barrel lock or disk tumbler barrel lock or other lock depending upon security concern conditions. In addition, depending on the application, the receiver member may configured and made from material to enable it to provide a self-destructibile or shearable, anti-tampering feature. For example, regarding lower security, in an example embodiment, the ring may be fastened using threads and a tamper evidence seal may be used either through the ring or fastening tabs to discourage tampering. The ring is may be a light gauge stainless steel. The fastening member material can be variable, but could be aluminum in this instance. For example, regarding mid-range security, in an example embodiment, the ring is fastened and then locked with plunger barrel lock. The ring is made of stainless steel. The receiver member is made of stainless steel. The fastener receiver is made of aluminum or stainless. For example, regarding higher security, in an example embodiment, the ring is fastened and then locked with high security disk tumbler barrel lock. The ring is made of a case hardened carbon steel ring. The lock receiver is made of case hardened carbon steel. The fastener receiver is made of stainless or case hardened carbon steel.

It should be recognized that in an exemplary embodiment, the shaft member comprises a first axis 130 and the shaft section comprises a second axis 132, as shown in FIGS. 5A and 5B, such that the shaft member 94 is coaxially insertable through the open end 52 of the shaft section 50 and into the cavity 100 of the fastening body portion 46 for tandem interconnection of the connective member 40 and locking member 90. In this way, the connective member, receiver member and locking member are coaxially alignable, such that the connective member and locking member are interconnectable in tandem. In addition, in one exemplary embodiment, the shaft section of the fastening member is insertable into the bore of the receiving member in a first direction 134. On the other hand, the shaft member 94 of the locking member is insertable into the bore 96 of the receiving member and then into the open end of the shaft section in a second direction 136 substantially opposite the first direction. It should be noted that the mounting of and insertion or installation direction and the connective member and receiver member, as well as the locking member may be reversible as desired to foster installation or rotation of the connective member by either a left-handed or right-handed user. In addition, other embodiments enable one-sided insertion and nested installation of the connective and locking members to aid in preventing tampering.

In an example embodiment, referring again to FIGS. 5A-5D, and a system for securing an electricity meter to a meter socket box is provided. Ring 32 comprises the annular body portion having a split forming first and second ends of the annular body portion. The first tab member 38A is disposed on the first ring end, and the second tab member 38B is disposed on the second ring end. A tandem interconnection system 140 comprises a primary connector 142 and a secondary connector 144. The primary connector 142 comprises connective member 40 and receiver member 42 and the secondary connector 144 comprises the locking member 90, with the connective member being disposed on the first tab member. The connective member 40 includes the fastening member comprising a fastener body portion forming a head section and a shaft section; the shaft section forms the open end 52. The fastener body portion comprises the fastener interior surface defining cavity 100 extending axially from the open end and into at least the shaft section, however, as noted, preferably in an exemplary embodiment, the cavity of the fastener body portion extends axially from the open end 52 and completely through the shaft section 50 and into at least a portion of the head section 48. The exterior surface 60 of the shaft section forms thread member 62. In addition, as noted earlier, as shown in FIGS. 3A-3F and FIGS. 4A-4B, a receiver member 64 is disposed on the second tab member 38B, wherein the receiver member comprises an interior surface 66 defining a receiving groove 68 adapted to threadably receive the thread member of the shaft section, wherein the first and second tab members may be securable by the connective member and receiver member. Referring also to FIGS. 2A-2B, the first tab member 38A defines a first aperture 54A as noted and the fastening member 44 comprises a collar 70 suitable for supporting disposition of the fastening member through the first aperture. In addition, the second tab member 38B defines a second aperture 58B. The receiver member includes a support member for supporting disposition of the receiver member through the second aperture. In some embodiments, as shown in FIGS. 3A and 3B, support member 77 is suitable for nonrotatably supporting disposition of the receiver member through the second aperture. Turning again to FIGS. 5A-5D, the locking member 90 comprises head member 92 and shaft member 94, and the interior surface of the receiver member 42 further defines cylindrical bore 96 therethrough being adapted to receive the shaft member 94. As noted, the fastener interior surface is configured for interconnecting the shaft member. In one embodiment, the shaft member of the locking member includes at least one locking element. In an exemplary embodiment, the shaft member 94 preferably includes two locking elements 98A, 98B. The shaft member 94 of the locking member is insertable through the open end 52 of the shaft section 50 and into the cavity 100 of the fastener body portion. The fastener interior surface is configured for interconnecting with the at least one locking element in one embodiment.

As noted earlier, as shown in FIGS. 5A-5D, the interior surface of the head section forms at least one recess adapted to receive the at least one locking element. In an example embodiment, the interior surface of the head section forms recess 104. The shaft member 94 preferably includes two locking elements 98A, 98B, and the head section of fastener interior surface is configured for interconnecting with the two locking elements 98A, 98B, preferably disposed, in an exemplary embodiment, in opposing relation on the shaft member, for example, as shown in FIG. 5D.

In another example embodiment, a securing system for use with an electricity meter and a meter socket box is provided. Turning again to the various drawings in FIGS. 2A-7C, similar named elements denote similar reference characters throughout the several views. As shown in FIGS. 5A1 and 5A2, the system comprises a primary connector 142′ comprising a connective member and a receiver member. In a further embodiment, the system comprises a secondary connector 144′. The connective member comprises a fastening member comprising a fastener body portion forming a head section and a shaft section, the shaft section is insertable through a first aperture formed in a first tab member of a securing ring adapted for securing an electricity meter to a meter socket box. The shaft section forms an open end, and the fastener body portion comprises a fastener interior surface defining a cavity extending axially from the open end and into at least the shaft section. The exterior surface of the shaft section forms a thread member. A portion of the receiver member is insertable through second aperture formed in a second tab member of a securing ring adapted for securing an electricity meter to a meter socket box, the receiver member comprising an interior surface defining a receiving groove adapted to threadably receive the thread member of the shaft section, the first and second tab members being securable with the connective member and receiver member. The primary connector 142′ is configured for interconnection with a secondary connector 144′. In another embodiment, the system further comprises a secondary connector comprising a locking member comprising a head member and a shaft member. The interior surface of the receiver member further defines a cylindrical bore therethrough being adapted to receive the shaft member, such that the fastener interior surface is configured for interconnecting the shaft member. In a further embodiment of the system, the shaft member of the locking member comprises at least one locking element. The shaft member of the locking member is insertable through the open end of the shaft section and into the cavity of the fastener body portion and the fastener interior surface is configured for interconnecting with the at least one locking element.

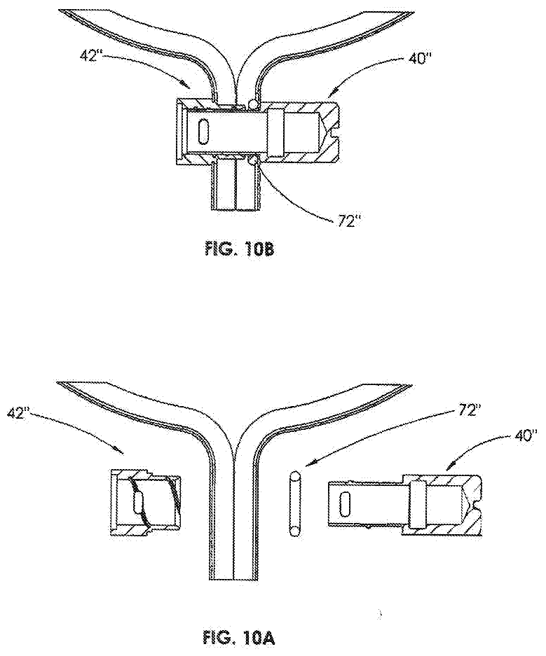

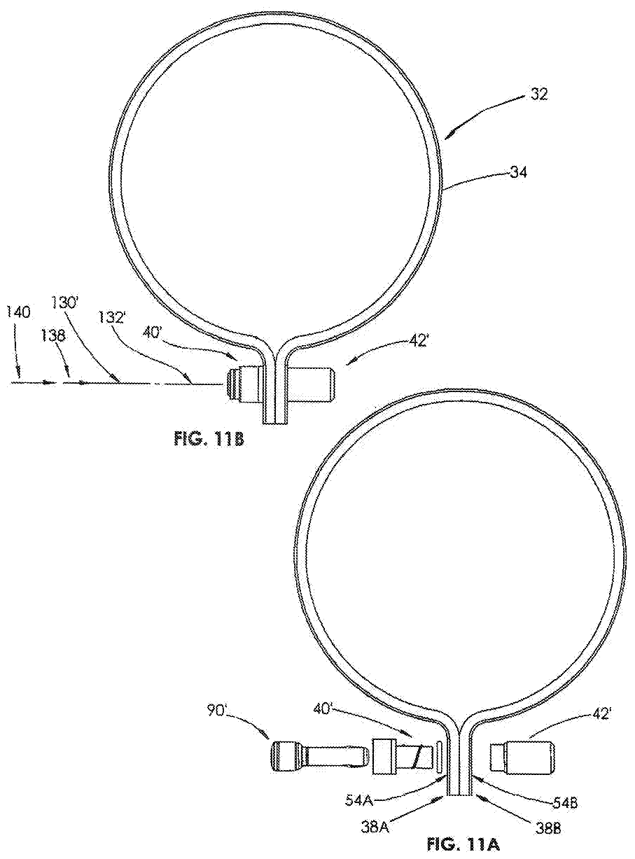

Turning again to FIGS. 3A-5C, regarding the fastening member, in some embodiments, the collar comprises an o-ring 72 for releaseably supporting disposition of the fastening member through the first aperture. In other embodiments, at least a portion of the collar is deformed so as to rotatably support the fastening member through the first aperture. In still other embodiments, such as shown in FIG. 10C, at least a portion of the collar comprises a support member 73 comprising an annular barb member 75 for nonreleaseably mounting the connective member through the first aperture. The barb member 75 or retaining barb may be disposed the fastening member or receiver member. The retaining barb is adapted to be pushed through a ring aperture on given tab member by plastically deforming the ring. The chamfer on the entry side of the barb facilitates pushing it into the aperture; and the flat on the back side inhibits removal. In still further embodiments, at least a portion of the collar comprises a support member having a diameter larger than the shaft section. Other methods of attaching the fastener or receiver member, in other example embodiments may also include at least a portion of the collar being swaged so as to rotatably support or nonrotatably support disposition of the fastening or receiver member through the first aperture. Further example embodiments may also include at least a portion of the collar being staked so as to rotatably support or nonrotatably support disposition of the fastening or receiver member through the respective aperture. However, as noted herein, it should also be recognized that the various support member mounting configurations also foster interchangeability in the event that the fastener member or receiver member needs to replaced. Also, it should be noted that the ring, connective member, receiver member as well as and locking member comprise various options and configurations in view of multi-range security modes, such as low, mid, high or as desired, as well as various interchangeability features discussed herein, including use of various grades and types of materials such as aluminum, steel, plastics or as known to a person of ordinary skill in the art. As noted, in some embodiments, the thread member comprises steel and the receiver member comprises aluminum.

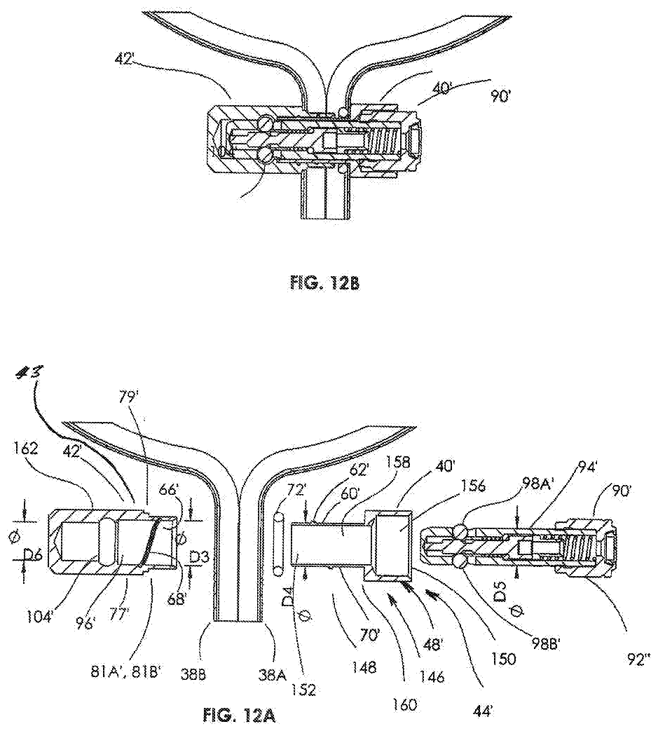

In further example embodiment, a system for securing an electricity meter to a meter socket box is provided. Referring now to FIGS. 11A-12B, a ring 32 is provided comprising an annular body portion having a split forming first and second ends of the annular body portion. A first tab member is 38A disposed on the first ring end, and a second tab member 38B is disposed on the second ring end. A hollow connective member 40′ is disposed on the first tab member, the hollow connective member comprises a fastener member 44′ comprising a fastener body 46′ forming a head 48′ and a shaft 50′, wherein the head comprises a head body 146 and the shaft comprises a shaft body 148, and wherein the head body forms a first open end 150 and defines a first cavity 156 extending axially from the first open end of the head body. The shaft body forms a second open end 152 defines a second cavity 158 extending axially from the second open end of the shaft body, the first cavity of the head body being in communication with the second cavity of the shaft body so as to form a continuous passageway 160 through the hollow connective member. The exterior surface 60′ of the shaft body forms a threaded member 62′. A receiver housing 42′ is disposed on the second tab member 38B, wherein the receiver housing comprises a retainer member 43 comprising an interior surface 66′ defining a receiving groove 68′ adapted to threadably receive the threaded member of the shaft section, the first and second tab members being securable with the hollow connective member and receiver member, such that the continuous passageway of the hollow connective is configured for receiving a locking member 90′. The interior surface of the receiver member is configured for interconnection with the locking member 90′. In a further embodiment, a locking member is included comprising a head member 92′ and a shaft member 94′. The interior surface of the retainer member further defines a cylindrical bore 96′ at least partially therethrough being adapted to receive the shaft member. The retainer member interior surface is configured for interconnecting the shaft member. In another embodiment, the shaft member of the locking member is insertable through the first open end 150 of the head body. The continuous passagewayl60 of the hollow connective member is adapted to receive the shaft member therethrough, and the shaft member of the locking member comprises at least one locking element. The interior surface 96′ of the retainer member is configured for interconnecting with the at least one locking element. Similar to the elements in as shown in FIGS. 5A-5D, the interior surface of the head section forms at least one recess 104′ adapted to receive the at least one locking element. In an exemplary embodiment, the interior surface of the head section forms one recess 104. The shaft member 94′ preferably includes two locking elements 98A′, 98B′, and the recess 104′ of the receiver housing interior surface is configured for interconnecting with the two locking elements 98A′, 98B′, preferably disposed, in an exemplary embodiment, in opposing relation on the shaft member, for example, as shown in FIG. 5D. As noted earlier, in an exemplary embodiment, the locking member 90′ comprises a barrel lock. For example, a type of barrel lock referred to as a SnapLock, shown in FIG. 6A, may be used; also, the various types shown in U.S. application Ser. No. 13/070,456, which is incorporated by reference in its entirety herein, may be used. In addition, a suitable disk tumbler lock may also be used having low-, mid-, or high-security applications, of the various types shown in U.S. Pat. No. 4,742,703, which is incorporated by reference in its entirety herein, may be used. In another embodiment, the locking member comprises a plunger lock; for example the types shown in U.S. application Ser. No. 13/070,456, which is incorporated by reference in its entirety herein, may be used. In addition, as shown FIGS. 11A-12B, it should be noted the diameters of the opening into the receiver housing, D3, D6, the connective member internal diameter D4, the shaft member D5 are sized and configured for coaxial alignment and insertion and interconnectability. In addition, the diameter of the head member, not shown, is sized so that it is shrouded in the head of the hollow connective member 40′. It should also be noted that in FIGS. 2A-7B, the head section forms a shroud with a annular recess receive and nest the head member of the barrel lock to protect it from tampering.

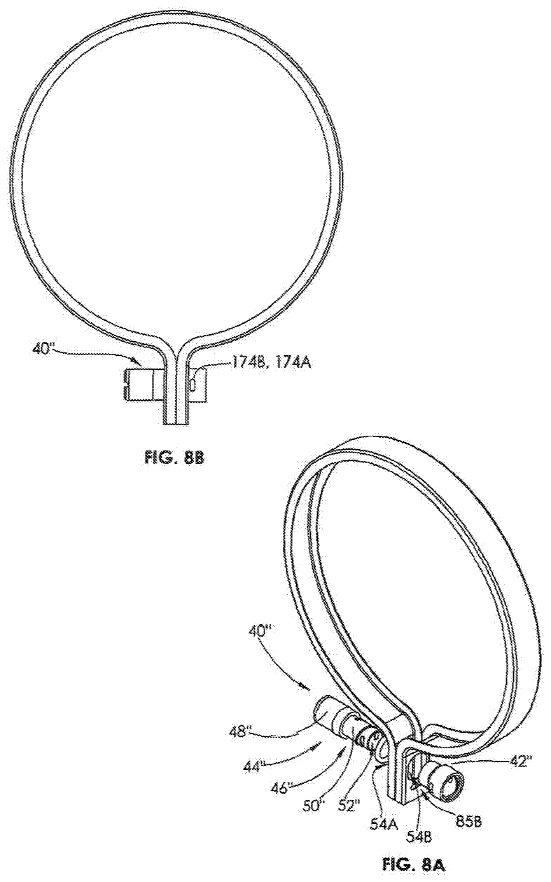

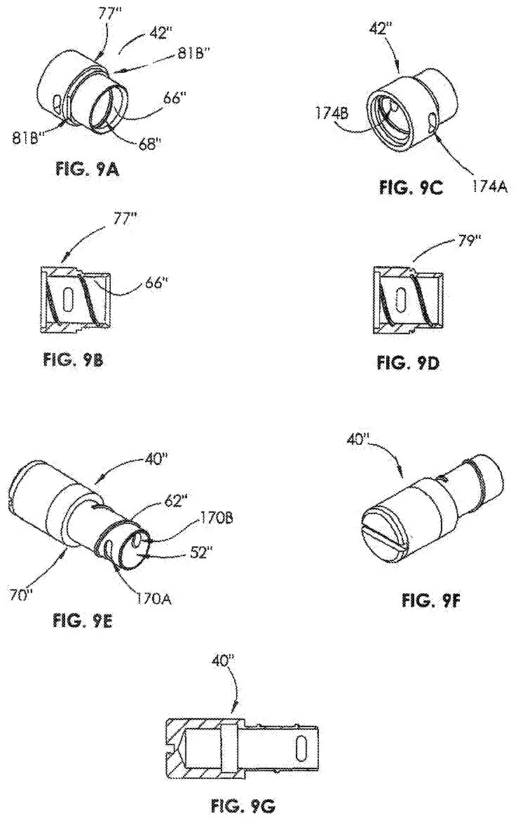

In another example embodiment shown in FIGS. 8A-10B, similar named elements denote similar reference characters throughout the several views. However, first and second alignment slots 170A, 170B are formed in the connective member 40″. First and second alignment slots 174A, 174B are formed in the receiver member 42″. After the connective member 40″ is screwed into and installed in the receiver member 42″, the first second alignment slots 170A, 170B are alignable with the first and second alignment slots 174A, 174B formed in the receiver member 42″. A wire seal tab (not shown), known to persons or ordinary skill in the art, is insertable through the first and second alignment slots 170A, 170B formed in the connective member 40″ and the first and second alignment slots 174A, 174B formed in the receiver member 42′. The seal tab is then sealable to indicate tampering.

Referring again to FIGS. 5A-5D, the interior surface of the receiver member comprises a shearable region 45. The shearable region 45 is disposed to form the receiving groove 68. The shearable region is adapted to shear when subject to a shear force of sufficient magnitude. The shear force of sufficient magnitude comprises a force of about 600 lbs. In some embodiments, the shearable region comprises aluminum and the thread member comprises steel. In an exemplary embodiment, which may be used for low-security applications, but possibly various other or also higher security applications, the shearable region comprises 6063T52 type aluminum and the thread member comprises 303 type steel. Alternatively, the thread could be the sheared element by making the receiving member out of 7075 aluminum and the fastening member out of 303 stainless steel.

In an example embodiment, the ring, connective member, receiver member and locking member is comprised of case hardened carbon steel to offer a higher level security protection, or Aluminum such as 6061T6511 to provide an economic but lower security level of protection. The receiver member is made of stronger material such as 7075T651 aluminum than fastener material such as 303 stainless steel so that threads on fastener shear when linear force of 1,000 pounds is applied. It should be noted that locks can withstand 2,000 pounds of pullout force before failing. The threads failing in the range of 600 to 1000 pounds of linear force prevents an attacker from using the threads to pull lock locking member out of recess in shaft.

Referring again to FIGS. 2A-5D, in an exemplary embodiment, the thread member comprises a square thread configuration. In some embodiments, the thread member comprises a thread configuration in the range of 2 threads per inch to 4 threads per inch, but other configurations may be used in other embodiments as well. In addition, with the thread configuration and spacing, the connective member is adapted to draw the first and second tab members together when rotated about two times or less, so as to enable a user to quickly draw together and secure the first and second tab members.

In use, in an example embodiment, the ring assembly or ring and tandem interconnection system, is designed to be used for low to medium level security. The primary intended use is to function as a low-security meter ring that is secured with a seal tab. Tightening the fastener member and the receiver member provides tight closure onto the meter so the seal can be closed tightly to ensure tampering with meter will require removal of the seal. When evidence of tampering is detected by the utility company, the operator can upgrade the security by inserting a barrel lock into the assembly and also install a seal. The barrel lock can be a plunger style, which is most likely, or a tumbler lock, or an electronic lock or any technology that complies with standard barrel lock dimensions. There are alternate embodiments of the apparatus that increases the level of security by utilizing different metals and case hardening.

Turning again to the embodiment, as shown in FIGS. 1 and 3, it should be noted that in certain embodiments, an interior diameter of the annular band 14 is selected to fit around a watthour meter and socket box flange combination in accord with industry standards, for example, in accord with the industrial standard for watthour meters set by the American National Standards Institute (“ANSI”). In other embodiments, however, an interior diameter of the annular band is selected to secure electrical meters of non-standard or proprietary sizes that do not meet the ANSI industrial standards for watthour meters. The attached figures illustrate an apparatus for securing a plurality of structures. For example, in one embodiment, the apparatus is used for securing a watthour meter to a socket box. The apparatus may also be used for creating a tamper-evident seal as will hereinafter be explained in further detail.

It should be understood that while descriptions and application representations apply to meter boxes, these devices could be used on many enclosures of similar configuration and design that may contain wires or other valuable material that must be protected from theft or tampering. Such applications may include traffic light enclosures, substation enclosures or the like and as noted herein.

It should be noted that the design described does not limit the scope of the embodiments of invention; the number of various elements may change, or various components may be added or removed to the above-described concept.

The foregoing disclosure and description of embodiments of the invention is illustrative and explanatory of the above and variations thereof, and it will be appreciated by those skilled in the art, that various changes in the design, organization, order of operation, means of operation, equipment structures and location, methodology, the use of mechanical equivalents, such as different types of components than as illustrated whereby different steps may be utilized, as well as in the details of the illustrated construction or combinations of features of the various elements may be made without departing from the spirit of the embodiments of the invention. As well, the drawings are intended to describe various concepts of embodiments of the invention so that presently preferred embodiments of the invention will be plainly disclosed to one of skill in the art but are not intended to be manufacturing level drawings or renditions of final products and may include simplified conceptual views as desired for easier and quicker understanding or explanation of embodiments of the invention. As well, the relative size and arrangement of the components may be varied from that shown and the embodiments of the invention still operate well within the spirit of the embodiments of the invention as described hereinbefore and in the appended claims. Thus, various changes and alternatives may be used that are contained within the spirit of the embodiments of the invention. It is therefore desired that the invention not be limited to these embodiments, and it is intended that the appended claims cover all such modifications as fall within the true spirit and scope of the invention.

Accordingly, the foregoing specification is provided for illustrative purposes only, and is not intended to describe all possible aspects of the example embodiments of the invention. It also will be appreciated by those skilled in the art, that certain various changes in the ordering of steps, ranges, interferences, spacings, components, hardware, and/or attributes and parameters, as well as in the details of the illustrations or combinations of features of the methods and system discussed herein, may be made without departing from the spirit of the embodiments of the invention. Moreover, while various embodiments of the invention have been shown and described in detail, those of ordinary skill in the art will appreciate that changes to the description, and various other modifications, omissions and additions may also be made without departing from either the spirit or scope thereof.

What is claimed is:

1. An apparatus for securing an electricity meter to a meter socket box, the apparatus comprising:
a ring comprising an annular body portion having a split forming first and second ends of the annular body portion;
wherein a first tab member is disposed on the first ring end, and a second tab member is disposed on the second ring end;
a connective member disposed on the first tab member, the connective member comprising a fastening member comprising a fastener body portion forming a head section and a shaft section, the shaft section forming an open end, and wherein the fastener body portion comprises a fastener interior surface defining a cavity extending axially from the open end and into at least the shaft section, and wherein the exterior surface of the shaft section forms a thread member; and
a receiver member disposed on the second tab member, wherein the receiver member comprises an interior surface defining a receiving groove adapted to threadably receive the thread member of the shaft section, the first and second tab members being securable by the connective member and receiver member, and wherein the interior surface of the receiver member is configured for receiving a locking member, the fastener interior surface being configured for interconnection with the locking member.

2. The apparatus of claim 1, and further comprising a locking member comprising a head member and a shaft member, and wherein the interior surface of the receiver member further defines a cylindrical bore therethrough being adapted to receive the shaft member, wherein the fastener interior surface is configured for interconnecting the shaft member.

3. The apparatus of claim 2, wherein the shaft member of the locking member comprises at least one locking element, the shaft member of the locking member being insertable through the open end of the shaft section and into the cavity of the fastener body portion, the fastener interior surface being configured for interconnecting with the at least one locking element.

4. The apparatus of claim 3, wherein the cavity of the fastener body portion extends axially from the open end and completely through the shaft section and into at least a portion of the head section.

5. The apparatus of claim 4, and wherein the interior surface of the head section forms at least one recess adapted to receive the at least one locking element.

6. The apparatus of claim 4, wherein the interior surface of the head section forms at least two recesses each being adapted to receive the at least one locking element.

7. The apparatus of claim 6, wherein the at least two recesses are adapted to incrementally receive the at least one locking element, the at least two recesses being formed in succession, wherein the shaft member may be incrementally inserted into the head section so as to draw together the first and second tab members to foster adjustably securing an electricity meter to a meter socket box.
